(19) United States
(12) Patent Application Publication
(10) Pub. No.: US 2021/0013348 A1
(43) Pub. Date: Jan. 14, 2021

(54) SOLAR CELL, SOLAR CELL MODULE, AND METHOD FOR MANUFACTURING SOLAR CELL

(71) Applicant: KANEKA CORPORATION, Osaka (JP)

(72) Inventors: Minoru MIYAMOTO, Toyooka-shi (JP); Yutaka YANAGIHARA, Toyooka-shi (JP); Takaaki MIURA, Toyooka-shi (JP)

(21) Appl. No.: 17/035,381

(22) Filed: Sep. 28, 2020

Related U.S. Application Data
(63) Continuation of application No. PCT/JP2019/009415, filed on Mar. 8, 2019.

(30) Foreign Application Priority Data
Mar. 30, 2018 (JP) 2018-069822

(51) Int. Cl. H01L 31/0216; H01L 31/0236

(52) U.S. Cl. CPC H01L 31/02168; H01L 31/022475; H01L 31/02366

(57) ABSTRACT

A solar cell includes a photoelectric conversion substrate having a first surface that includes a texture structure, a coating layer provided on the first surface and having an opening exposing the first surface, and an electrode in the opening. The unevenness of the surface of the coating layer has a larger height difference than a height difference of the texture structure of the first surface.

### CROSS-REFERENCE TO RELATED APPLICATION

This is a continuation of PCT International Application PCT/JP2019/009415 filed on Mar. 8, 2019, which claims priority to Japanese Patent Application No. 2018-069822 filed on Mar. 30, 2018. The disclosures of these applications including the specifications, the drawings, and the claims are hereby incorporated by reference in their entirety.

### TECHNICAL FIELD

The present disclosure relates to a solar cell, a solar cell module, and a method for manufacturing a solar cell.

### BACKGROUND

Solar cells include, on the surface of a photoelectric conversion substrate, a collector that collects charges generated on the substrate. Collectors are often formed by printing or plating. Collectors obtained by printing have the problem of a higher resistance. Thus, the formation of collectors by plating causing a lower interconnect resistance is focused on.

At the formation of collectors by plating, a coating layer functioning as a mask is disposed on the surface of a photoelectric conversion substrate. This coating layer also functions as a protective film that protects the surface of the photoelectric conversion substrate. This coating layer may be an insulating film such as an oxide film or a resin film. Among the films, a resin film is focused on as a coating layer because of its easier formation (see, e.g., International Patent Publication No. WO 2012/029847).

### SUMMARY

However, typical coating layers have a smooth surface to disperse the electric field concentration. On the other hand, the surfaces of photoelectric conversion substrates have a texture structure to reduce surface reflection or improve the light confinement effect. A smooth surface of a coating layer has the problems of hindering an effective function of the texture structure of the photoelectric conversion substrate and degrading the optical characteristics of the photoelectric conversion substrate.

The present inventors found that the surface conditions of a coating layer affected not only the optical characteristics but also the productivity in a plating step for forming collectors.

It is an objective of the present disclosure to achieve a solar cell with excellent optical characteristics and a higher productivity.

A solar cell according to an aspect of the present disclosure includes: a photoelectric conversion substrate having a first surface that includes a texture structure; a coating layer provided on the first surface and having an opening exposing the first surface; and an electrode in the opening. The coating layer has unevenness with a larger height difference than a height difference of the texture structure of the first surface.

The solar cell according to the present disclosure has improved optical characteristics and a higher productivity.

### BRIEF DESCRIPTION OF THE DRAWINGS

FIG. 1 is a cross-sectional view of a solar cell according to an embodiment.

FIG. 2 is an enlarged cross-sectional view of a coating layer.

FIG. 3 is an enlarged plan view of the coating layer.

FIG. 4A is a cross-sectional view showing a step of a method of manufacturing the coating layer.

FIG. 4B is a cross-sectional view showing another step of the method of manufacturing the coating layer.

FIG. 4C is a cross-sectional view showing further another step of the method of manufacturing the coating layer.

FIG. 5 is a plan view of a solar cell according to the embodiment.

FIG. 6A is a cross-sectional view showing a step of a method of manufacturing an electrode.

FIG. 6B is a cross-sectional view showing another step of the method of manufacturing the electrode.

FIG. 6C is a cross-sectional view showing further another step of the method of manufacturing the electrode.

### DETAILED DESCRIPTION

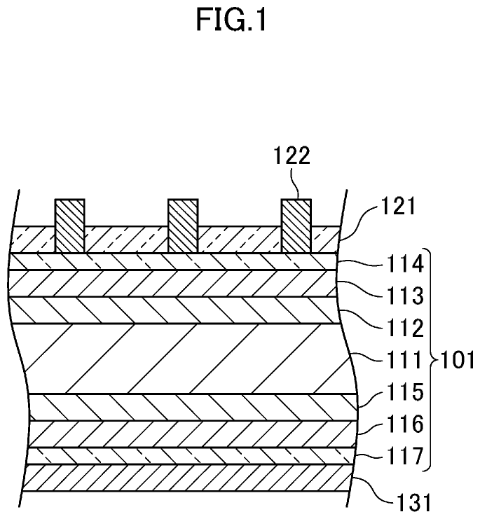

As shown in FIGS. 1 to 3, a solar cell according to this embodiment includes a photoelectric conversion substrate 101, a coating layer 121, and electrodes 122. The photoelectric conversion substrate 101 has a first surface with a texture structure. The coating layer 121 is located on the first surface and has openings exposing the first surface. The electrodes 122 are located in the openings.

—Photoelectric Conversion Substrate—

In the present disclosure, the texture structure of the first surface of the photoelectric conversion substrate correspond to “projections and recesses of the first surface”, and may also be referred to as the “first surface's texture.”

In this embodiment, the photoelectric conversion substrate 101 is of a hetero-junction type. In the example shown in FIG. 1, an n-type single-crystal silicon substrate 111 includes, on a first surface (i.e., a light-incident surface), an i-type amorphous silicon layer 112, a p-type amorphous silicon layer 113, and a transparent conductive layer 114 formed sequentially. The silicon substrate 111 includes, on a second surface (i.e., a back surface), opposite to the first surface, an i-type amorphous silicon layer 115, an n-type amorphous silicon layer 116, and a transparent conductive layer 117 formed sequentially. The transparent conductive layer 117 is covered with a back electrode 131.

In this embodiment, the silicon substrate 111 has a texture structure including projections and recesses on the first surface and the second surface. The silicon layers and the transparent conductive layers on and above the silicon substrate 111 have a texture structure reflecting the texture structure of the silicon substrate 111.

—Coating Layer—

In the present disclosure, the coating layer on the first surface and with the openings exposing the first surface is a layer on the first surface's texture, whereas the openings are openings exposing the first surface together with the first surface's texture.

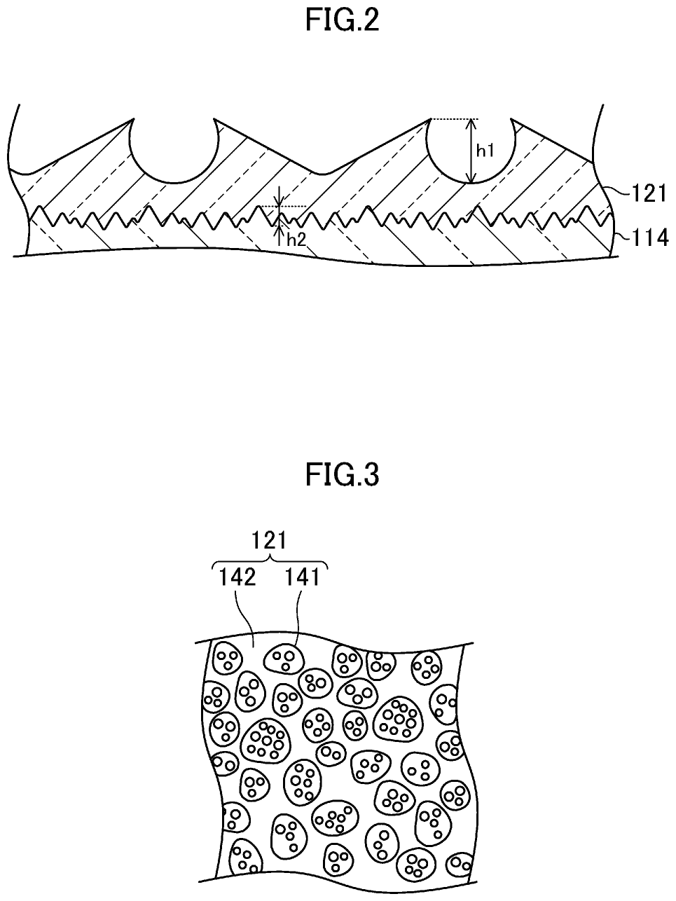

As shown in FIGS. 2 and 3, the coating layer 121 has a surface with projections and recesses in this embodiment. The projections and recesses of the coating layer, that is, the unevenness on the surface of the coating layer, may also be referred to as the “coating layer's unevenness.” In this embodiment, the unevenness of the coating layer 121, that is, the “coating layer's unevenness” has a height difference h1 which is larger than a height difference h2 of the texture structure of the transparent conductive layer 114. This is one of the characteristic configurations of the solar cell according to this embodiment. Note that the height difference h2 of the texture structure of the transparent conductive layer 114 is substantially equal to the height difference of the first surface's texture. As shown in FIG. 2, the height difference of the unevenness or the texture structure is a height difference between the uppermost point of the projections and the lowermost point of the recesses. The height difference of the unevenness and the texture structure may be measured by a method specified in Examples.

The present inventors found that formation of the coating layer's unevenness with a large height difference on the surface of the coating layer 121 improved the water repellency of the surface of the coating layer 121. In the plating step for forming the electrodes 122, this configuration significantly reduces a residual plating solution or rinse liquid and the time required for the step. In addition, the formation of the coating layer's unevenness with a large height difference on the surface of the coating layer 121 reduces reflection on the surface and improves the light confinement effect.

Specifically, the height difference h1 of the coating layer's unevenness may fall within the following range in view of improving the water repellency and the optical characteristics. The lower limit may be preferably 4 μm or more, and more preferably 5 μm or more, whereas the upper limit may be preferably 20 μm or less, and more preferably 10 μm or less. The height difference may fall between two values within the range from 4 μm to 20 μm. In addition, the projections of the coating layer's unevenness are arranged like islands in one preferred embodiment.

On the other hand, the texture structure on the surface of the photoelectric conversion substrate 101 including the projections and recesses of first surface is usually formed utilizing the anisotropy in the etching rate depending on the plane orientation. For this reason, the height difference of the texture structure of the surface of the photoelectric conversion substrate 101 usually falls within a range from about 0.5 μm to about 3 μm.

The coating layer 121 may be a transparent insulating layer, but is a transparent resin layer in one preferred embodiment in view of reducing a residual plating solution. In particular, the resin layer may be preferably made of a cured product of a curable resin composition in view of maintaining the coating layer's unevenness. The “curable resin composition” is a resin composition that is curable by applying energy of heat and/or light, for example. The “curable resin composition” may be, for example, a thermosetting resin composition, a photocurable resin composition, or an active energy ray-curable resin composition in one preferred embodiment. As will be described later, a photocurable resin composition may be selected in a more preferred embodiment.

Such a curable resin composition may be cured by addition polymerization, such as radical polymerization or ion polymerization, or by condensation polymerization. In view of easily forming the coating layer's unevenness, the resin composition is cured by addition polymerization hardly causing a change in volume in one preferred embodiment. In view of easily forming the coating layer's unevenness and further improving the productivity, the resin composition is cured by rapid radical polymerization in a more preferred embodiment. A polymerization initiator contained in the resin composition to initiate radical polymerization is one that initiates polymerization through application of the energy of generally used heat and/or light, for example, in one preferred embodiment. Among photopolymerization initiators, one that initiates polymerization mainly through application of the energy of light is selected in one preferred embodiment to obtain a photocurable, particularly UV-curable resin composition capable of rapid curing.

The resin composition of the resin layer constituting the coating layer 121 has a refractive index ranging from 1.5 to 2 at a wavelength of 600 nm. In one preferred embodiment, the resin composition has an optical transparency of 90% or more within a range from 360 nm to 800 nm, in a case in which the pure material is a film with a thickness of 20 μm.

Specific examples of the resin composition constituting the resin layer may include an epoxy-based resin, a urethane-based resin, an acrylic-based resin, a polypropylene-based resin, a polystyrene-based resin, a polyester-based resin, and a styrene-based elastomer resin. Additional examples are condensation polymers such as a polyimide-based resin (i.e., a transparent polyimide-based resin), a polyarylate-based resin, and a polycarbonate-based resin.

Among these, a resin layer formed by curing a resin composition containing a curable acrylic-based resin as a main component is preferably used in view of the transparency and weather resistance. The “resin composition containing a curable acrylic-based resin as a main component” may contain the curable acrylic-based resin at the following ratio with respect to the total amount (i.e., 100 mass %) of the resin composition. The ratio may be preferably higher than 50 mass %, more preferably higher than 70 mass %, further more preferably higher than 80 mass %, and yet more preferably from 95 to 99.7 mass %. In view of easily forming the unevenness and further improving the productivity, the resin composition may contain one or more kinds selected from the group consisting of amide-based, carboxylic acid-based, urea-based, polyethylene oxide-based, and silicate-based thixotropic agents. The thixotropic agent may be added to obtain a required thixotropic index (TI). The ratio of the thixotropic agent to the total amount of the resin composition may be the residual other than the curable acrylic-based resin. The ratio may preferably be 0.3 mass % or more, and preferably 30 mass % or less and more preferably 5 mass % or less.

In view of effectively forming the coating layer's unevenness with a high productivity, the thixotropic index (TI) of the resin composition is preferably 1.5 or more, more preferably 3 or more, further more preferably 6 or less, and yet more preferably 5 or less.

The coating layer 121 may be formed by the following step of forming a coating layer. The step of forming a coating layer includes, for example, a sub-step of printing a curable resin composition to form an uncured coating layer, and a sub-step of curing the curable resin composition of the uncured coating layer into the coating layer.

In the sub-step of printing, an uncured coating layer 121A may be formed on the first surface of the photoelectric conversion substrate, specifically, for example, on the transparent conductive layer 114 by printing. The printing may be screen printing, gravure printing, or offset printing, for example, among which screen printing is preferred.

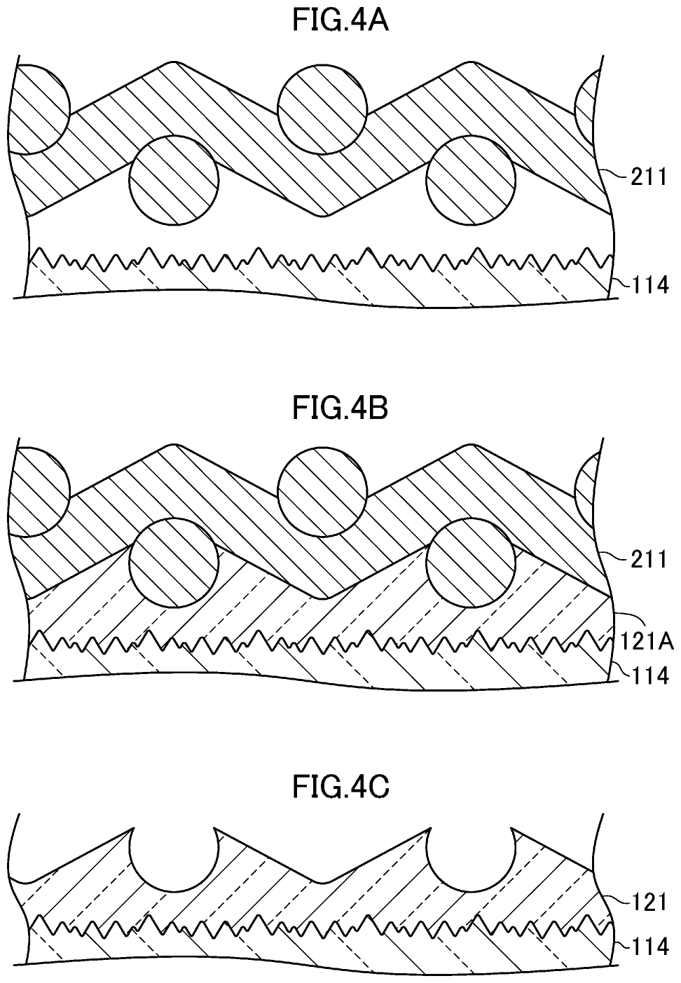

In an example, first, as the sub-step of printing, the photoelectric conversion substrate 101 with the texture structures (i.e., the first surface's texture and second surface's texture) is prepared as shown in FIG. 4A. A screen printing plate 211 is disposed on the transparent conductive layer 114. In the screen printing plate 211, the meshes in the locations of the electrodes 122 are blocked by an emulsion, for example.

Next, as shown in FIG. 4B, the resin composition is extruded from the screen printing plate 211 by a squeegee or a roller, and the resin composition to be the coating layer 121 is coated on the transparent conductive layer 114 to transfer a pattern.

Next, as the sub-step of curing, the uncured coating layer 121A is cured, as shown in FIG. 4C. The uncured coating layer 121A may be cured by applying appropriate energy in accordance with the type of resin composition to be used, to initiate polymerization. As described above, the energy of heat and/or light is used for curing in one preferred embodiment, among which the energy of light is used in a more preferred embodiment. This provides the coating layer 121 with the coating layer's unevenness caused by the mesh structure of the screen printing plate 211. In this embodiment, the coating layer's unevenness is formed due to the unevenness of the surface of the uncured coating layer 121A in one preferred embodiment. The unevenness of the surface of the uncured coating layer 121A is the same as the coating layer's unevenness in a more preferred embodiment.

In the case of forming the coating layer 121 by screen printing, setting the thixotropic index (TI), described above, of the resin composition used for the printing preferably to 1.5 or more and more preferably to 3 or more, and preferably to 6 or less and more preferably to 5 or less exhibits a significant effect in view of forming the unevenness. The TI of the resin composition may be controlled by the kind and the amount of the thixotropic agent, for example. The TI of the resin composition may be measured by the method shown in Examples. In Examples described later, the thixotropic agent is added within a preferable range to achieve a desired value T1 and prepare samples according to Examples.

In the case of forming the coating layer 121 by screen printing, the resin composition used for printing may have the following viscosity in view of the printability. The lower limit may be preferably 100 Pa·s or more, and more preferably 150 Pa·s or more, whereas the upper limit may be preferably 1500 Pa·s or less, and more preferably 1200 Pa·s or less. The viscosity may fall between two values within the range from 100 Pa·s to 1500 Pa·s. The viscosity of the resin composition may be measured by the method specified in Examples. In view of forming the unevenness in the case of forming the coating layer 121 by screen printing, both the TI and the viscosity of the resin composition used for the printing fall within the predetermined ranges described above in one preferred embodiment.

In one preferred embodiment, the resin composition is cured as soon as possible after the application of the resin composition so as not to lose the formed unevenness. The resin composition may be completely cured at this moment, or temporarily cured to the extent that the unevenness can be maintained and then completely cured. While the curing method may be appropriately selected in accordance with the resin composition, photocuring with an ultraviolet ray, for example, may be selected in one preferred embodiment in view of the rapidity.

If the coating layer 121 is formed by screen printing using a resin composition with at least the TI, among the TI and the viscosity, in the predetermined range, projections are formed in the openings of the meshes, whereas recesses are formed in the locations of the wires. In addition, the recesses are deeper at the intersections of the wires. Accordingly, as shown in FIG. 3, a plurality of projections 141 may be formed like islands on the surface. However, such island-like projections are not formed in some cases. With an increase in the mesh count of the screen printing plate 211, the size of each island-like projection 141 decreases. The size of each projection 141 affects the water repellency of the surface of the coating layer 121 and the optical characteristics. In view of improving the water repellency of the surface of the coating layer 121, the screen printing plate 211 may have the following mesh count (the number of wires constituting meshes per inch). The lower limit may be preferably 100 or more, more preferably 300 or more, and further more preferably 400 or more, whereas the upper limit may be preferably 750 or less, and more preferably 650 or less. The mesh count may fall between two values within the range from 100 to 750.

If the screen printing is employed, the curable resin composition is applied via the screen printing plate, and thus the thickness of the screen printing plate 211 allows adjustment of the depth of the recesses 142. The depth of the recesses 142 affects the water repellency of the surface of the coating layer 121 and the optical characteristics. The thickness of the screen printing plate 211 (hereinafter also referred to as a “mesh thickness”) may depend on the thickness of the wires constituting the meshes and whether or not calendering (smoothening) is performed. With respect to the wire diameter, the lower limit may be preferably 10 μm or more, and more preferably 13 μm or more, whereas the upper limit may be preferably 30 μm or less, and more preferably 20 μm or less. The wire diameter may fall between two values within the range from 10 μm to 30 μm. With respect to the mesh thickness, the lower limit may be preferably 10 μm or more, and more preferably 15 μm or more, whereas the upper limit may be preferably 50 μm or less, and more preferably 30 μm or less. The mesh thickness may fall between two values within the range from 10 μm to 50 μm.

If the screen printing is employed as the sub-step of printing, the surface of the uncured coating layer 121A, to which the mesh structure of the screen printing plate has been transferred, is formed in the sub-step of printing. In the sub-step of curing following the sub-step of printing, the uncured coating layer 121A is cured, thereby forming the surface of the coating layer 121 with the coating layer's unevenness, onto which the mesh structure of the screen printing plate has been transferred. Thus, preferably in this embodiment, the unevenness of the surface of the screen printing plate is maintained.

The coating layer 121 formed eventually may have the coating layer's unevenness with the height difference h1 within the following range in view of improving the water repellency and the optical characteristics. The lower limit may be preferably 4 μm or more, and more preferably 5 μm or more, whereas the upper limit may be preferably 20 μm or less, and more preferably 10 μm or less. The height difference may fall between two values within the range from 4 μm to 20 μm.

—Electrode—

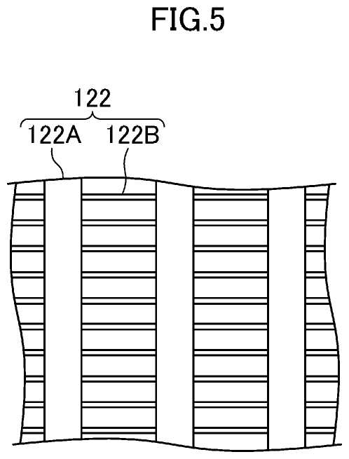

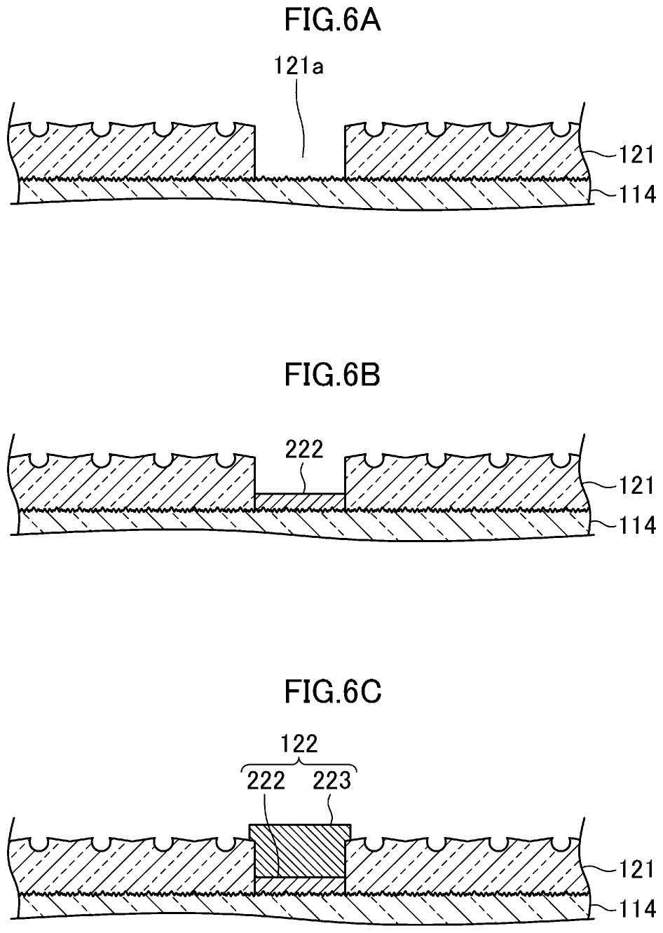

The electrodes 122 may be formed in the openings of the coating layer 121. Each electrode 122 is a collector including a bus bar electrode 122A and finger electrodes 122B, as shown in FIG. 5. Each electrode 122 may be formed, for example, as follows. First, as shown in FIG. 6A, the coating layer 121 with an opening 121a exposing the transparent conductive layer 114 is formed. Next, the photoelectric conversion substrate 101 with the coating layer 121 thereon is immersed in a plating bath to form a nickel plating layer 222 on the transparent conductive layer 114 by electrolytic plating. Next, as shown in FIG. 6C, a copper plating layer 223 is formed to fill the opening 121a.

The coating layer 121 functions as a mask for patterning the electrode 122 in the plating step for forming the electrode 122. The coating layer 121 also functions as a protective film for protecting the surface of the photoelectric conversion substrate 101.

At the formation of the electrode 122, the photoelectric conversion substrate 101 with the coating layer 121 is immersed in a plating solution. If the coating layer 121 is a resin layer having unevenness on the surface, the plating solution hardly remains on the surface of the coating layer 121 after the substrate is taken out of the plating solution. In addition, in the rising step after the plating, cleaning water hardly remains on the surface of the coating layer 121 after the substrate is taken out of the cleaning water after immersion. This greatly reduces the take-out amount of plating solution or cleaning water, which is expected to lead to long-term process stability and a significant reduction in the costs of an additional liquid to be supplied. In a drying step after the rinsing step, since the cleaning water hardly remains on the surface of the coating layer 121, the drying time can be reduced to about 1/10.

Preferably, in view of improving the productivity in the plating step, the surface of the coating layer 121 has a higher water repellency. Specifically, with respect to the contact angle of the surface with water, the lower limit may be preferably 90° or more, and more preferably 95° or more. The larger the contact angle, the better. However, the upper limit may be preferably 110° or less, and more preferably 105° or less in view of the characteristics of the material and the uneven structure. The contact angle may fall between two values within the range from 90° to 110°.

The thicknesses of the nickel plating layer 222 and the copper plating layer 223 are not particularly limited. For example, the nickel plating layer may have a thickness of about 0.5 whereas the copper plating layer 223 may have a thickness of about 15 Each electrode 122 may have not only such a double-layer structure but any other structure. For example, another nickel plating layer or a noble metal plating layer may be stacked on the copper plating layer 223. Alternatively, the electrodes 122 may have a single layer, or a stack, of the following: copper, nickel, tin, aluminum, chromium, silver, gold, zinc, lead, palladium, or a mixture thereof.

In this embodiment, the photoelectric conversion substrate 101 has the hetero-junction structure, that is, the texture structures on both sides. However, the back surface may not have a texture structure. An example in which the back electrode 131 covers the entire back surface has been described. However, the back electrode may be patterned. In addition, the back surface may also have a coating layer and a collector having similar configurations to those on the incident surface.

The materials of the transparent conductive layers 114 and 117 on the photoelectric conversion substrate 101 are not particularly limited but may be a conductive oxide such as a zinc oxide, an indium oxide, and a tin oxide, or a composite oxide thereof. Among oxides, an indium tin oxide (ITO) is selected in one preferred embodiment.

While an example has been described in this embodiment in which the silicon substrate 111 is of the n-type, the silicon substrate may also be of the p-type. An example has been described in which the p-type conductive silicon layer is stacked on the light-incident surface and the n-type conductive silicon layer is stacked on the back surface. Instead, an n-type silicon layer may be stacked on the light-incident surface and a p-type silicon layer may be stacked on the back surface. The material of the conductive silicon layer is not limited to amorphous silicon but may be microcrystalline silicon that is partially crystalline, an amorphous silicon alloy, or a microcrystalline silicon alloy. An example in which the i-type silicon layer is interposed between the silicon substrate and the conductive silicon layer has been described. However, the i-type silicon layer may not be provided.

The photoelectric conversion substrate 101 is not limited to the hetero-junction type. The substrate may have any structure as long as at least one surface has a texture structure and a collector.

—Solar Cell Module—

The solar cells according to this embodiment may be encapsulated by an encapsulant into a module. The solar cells are modularized by an appropriate method. For example, bus bar electrodes of a plurality of solar cells may be connected in series or in parallel and encapsulated by an encapsulant and a glass plate into a module.

The solar cell module according to this embodiment includes the solar cell according to the embodiment. The solar cell module according to this embodiment preferably includes a cover glass, a transparent sealing resin layer, the above-described solar cell, a back-surface sealing resin layer, and a back-surface protective member that are arranged sequentially from the light-incident side. The solar cell module according to this embodiment has an ultraviolet shielding effect due to the cover glass in addition to the effect of the coating layer made of the cured product of the resin composition. The solar cell module therefore has excellent long-term reliability required for a solar cell, and can be, for example, used outdoors for over a necessary guarantee period, 20 years. A coating layer made, for example, of a cured product of a curable acrylic-based resin composition with excellent light resistance and transparency further improves the long-term reliability, for example.

The material of the transparent sealing resin layer and the back-surface sealing resin layer is preferably an ethylene-vinyl acetate (EVA) copolymer resin. The copolymerization of the vinyl acetate reduces the crystallinity of the polyethylene, and thus improves the transparency and flexibility. Accordingly, the unevenness of the coating layer functions more effectively. The material of the back-surface protective member is not particularly limited but may be a material capable of securing required weather resistance, heat resistance, moisture resistance, and electrical insulation properties, for example. For example, a laminated film including an aluminum foil between plastic films or a cover glass may be used.

### EXAMPLES

Now, the invention according to the present disclosure will be described in more detail with reference to Examples. The following Examples are illustrative only and are not intended to limit the invention according to the present disclosure.

<Measurement of Height Difference>

The height difference was measured using a scanning electron microscope (SEM) TM3030plus manufactured by Hitachi High-Tech Corporation. First, the substrate was cut by any of various methods to observe the cross-section of the substrate. The uppermost and lowermost points of the texture structure and the surface of the coating layer were confirmed. The cross-section was observed near the center of the substrate in a field of view of 150 μm per point. The difference between the uppermost and lowermost points in the observation area was obtained. The measurement was performed at two points, and the average of the measurement results was taken as the height difference between the projections and recesses.

<Measurement of Characteristics of Resin Composition>

The viscosity of the resin composition was measured using a cone-plate viscometer RE-115U manufactured by TOKI SANGYO CO., LTD. The thixotropic index (TI) indicates the ratio of the viscosity at a low shear rate to the viscosity at a high shear rate. The TI here is the ratio of the viscosity ηa at the time when the viscometer operates at the speed X [rpm] to the viscosity ηb at the time when the viscometer operates at the speed 10× [rpm] that is ten times the viscosity ηa. In short, the thixotropic index was obtained by the following Equation 1. The viscosity of the resin composition was the value measured at a high shear rate.

TI=ηa/ηb (1)

<Measurement of Contact Angle>

The contact angle of the surface of the coating layer with water was measured using a portable contact angle meter PCA-1 manufactured by Kyowa Interface Science Co., Ltd.

<Measurement of Drying Time>

The drying time was measured as follows. The photoelectric conversion substrate after the completion of the plating step was immersed in cleaning water, taken out of the cleaning water, and held still. The time until the residual water drops disappear from the surface of the substrate was observed visually.

### Example 1

A photoelectric conversion substrate of a hetero-junction type having the configuration shown in FIG. 1 was prepared. The height difference of the surface of the transparent conductive layer on the first surface was about 1 μm to 2 μm.

A screen printing plate with a mesh count of 640, a wire diameter of 15 μm, and a mesh thickness of 21 μm was disposed on the transparent conductive layer, and an acrylic-based resin A was applied onto the screen printing plate. Soon after the application, the acrylic-based resin A was irradiated with light and temporarily cured. After that, the acrylic resin A was completely cured into a coating layer. The acrylic-based resin A had a viscosity of 243 Pa·s and a TI of 4.8.

The height difference h1 between the projections and recesses of the surface of the coating layer (the coating layer's unevenness) was 5 μm. The contact angle was 95°, and the drying time was 15 sec.

### Example 2

The acrylic-based resin A was replaced with an acrylic-based resin B with a viscosity of 255 Pa·s and a TI of 3.0. The other conditions were the same as in Example 1.

The height difference h1 of the coating layer's unevenness was 5 μm. The contact angle was 95°, and the drying time was 15 sec.

### Comparative Example 1

The acrylic-based resin A was replaced with an acrylic-based resin C with a viscosity of 96 Pa·s and a TI of 1.2. The other conditions were the same as in Example 1.

The height difference h1 of the coating layer's unevenness was almost 0 μm (i.e., no unevenness was observed). The contact angle was 85°, and the drying time was 150 sec.

Table 1 collectively shows the conditions and results of Examples and Comparative Example.

TABLE 1

| | | | | Comparative |
|---|---|---|---|---|
| | | Example 1 | Example 2 | Example 1 |
| Resin | TI | 4.8 (0.1/1.0 | 3.0 (2/20 | 1.2 (0.5/5.0 |
| Composition | | rpm) | rpm) | rpm) |
| | Viscosity (Pa · s) | 243 (1.0 | 255 (20 | 96 (5.0 |
| | | rpm) | rpm) | rpm) |

| | | | |
|---|---|---|---|
| Height Difference (μm) | 5 | 5 | 0 |
| Contact Angle (°) | 95 | 95 | 85 |
| Drying Time (sec) | 15 | 15 | 150 |

Note that the description in the parentheses in the row of the “TI” in Table 1 means (the speed X [rpm] of the viscometer/10× [rpm] that is the ten times the speed X). The description in parentheses in the row of the “viscosity” means the speed [rpm] at the time of measurement.

1. A solar cell, comprising:
a photoelectric conversion substrate having a first surface that includes a texture structure;
a coating layer provided on the first surface and having an opening exposing the first surface; and
an electrode in the opening,
the coating layer having unevenness with a larger height difference than a height difference of the texture structure of the first surface.

2. The solar cell of claim 1, wherein
the unevenness of the coating layer has the height difference ranging from 4 μm to 20 μm.

3. The solar cell of claim 1, wherein
the coating layer is made of a cured product of a curable resin composition.

4. The solar cell of claim 3, wherein
the coating layer is made of a cured product of a photocurable resin composition.

5. The solar cell of claim 3, wherein
the resin composition contains a curable acrylic-based resin as a main component.

6. The solar cell of claim 5, wherein
the resin composition contains:
95 mass % to 99.7 mass % of the curable acrylic-based resin with respect to a total amount of the resin composition; and
0.3 mass % to 5 mass % of one or more kinds selected from the group consisting of amide-based, polyethylene oxide-based, and silicate-based thixotropic agents with respect to the total amount.

7. The solar cell of claim 1, wherein
a contact angle of a surface of the coating layer with water ranges from 90° to 110°.

8. The solar cell of claim 1, wherein
the unevenness of the coating layer includes a plurality of projections that are arranged like islands.

9. A solar cell module comprising:
a cover glass; a transparent sealing resin layer; the solar cell according to claim 1; a back-surface sealing resin layer, and a back-surface protective member that are arranged sequentially from a light-incident side.

10. A method of manufacturing a solar cell, the solar cell including:
a photoelectric conversion substrate having a first surface that includes texture structure;
a coating layer provided on the first surface and having an opening exposing the first surface; and
an electrode in the opening,
the coating layer having unevenness with a larger height difference than a height difference of the texture structure of the first surface,
the method comprising a step of forming the coating layer including:
a sub-step of printing a curable resin composition on the first surface to form an uncured coating layer; and
a sub-step of curing the uncured coating layer to form the coating layer through application of energy of heat and/or light;
wherein the uncured coating layer has a surface including unevenness that is the same as the unevenness of the coating layer.

11. The method of claim 10, wherein
the printing is screen printing in which the curable resin composition is applied via a screen printing plate, and the screen printing plate has a mesh count ranging from 300 to 750.

12. The method of claim 10, wherein
the resin composition has a thixotropic index ranging from 1.5 to 6.

13. The method of claim 10, wherein
in the sub-step of curing, the energy applied to the uncured coating layer is the light.
